(19) United States
(12) Patent Application Publication
(10) Pub. No.: US 2007/0080452 A1
(43) Pub. Date: Apr. 12, 2007

(54) Bump structure and its forming method

(75) Inventors: Chen-Ya- Chi, Tainan (TW); Chun-Ying Lin, Tainan (TW); An-Hong Liu, Tainan (TW); Yi-Chang Lee, Tainan (TW); Hsiang-Ming Huang, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS Technologies (Bermuda) Ltd.; ChipMOS Technologies Inc.

(21) Appl. No.: 11/514,329

(22) Filed: Sep. 1, 2006

(30) Foreign Application Priority Data
Sep. 9, 2005 (CN) 094131169

(51) Int. Cl. H01L 23/48; H01L 23/52; H01L 29/40; H01L 21/44

(52) U.S. Cl. 257/737; 438/612

(57) ABSTRACT

A bump structure mainly includes a metal core, a buffer encapsulant, and a metal cap where the metal core is a stud bump formed by wire bonding. The buffer encapsulant encapsulates the metal core. A metal cap is formed on the top surface of the buffer encapsulant and is electrically connected to the metal core. Therefore, the bump structure possesses excellent resistance of thermal stress to reduce or even eliminate metal fatigue in the bump without causing electrical shorts in the package.

### FIELD OF THE INVENTION

The present invention relates to a semiconductor device, and more particularly to a bump structure and its forming method.

### BACKGROUND OF THE INVENTION

Recently, more and more semiconductor devices run at higher frequencies such as CPU, DDR2, or DDR3 DRAM, so that the conventional packages can not meet the requirements of high speed applications. The flip chip packages and the wafer-level packages (WLP) have been developed for high speed applications to reduce the transmitting lengths between the chip and the substrate to increase the operation frequencies. As revealed in R.O.C. Taiwan Patent publication No. 200518289, conventional bumps are solder bumps or metal plated bumps such as gold, aluminum, copper, etc. Since the coefficients of thermal expansion (CTE) of chips and substrates are different due to different materials, bumps will experience thermal stresses during temperature changes. Eventually metal fatigue will induce in the bumps leading to bump breakage and failure leading to electrical shorts in the packages.

### SUMMARY OF THE INVENTION

The main purpose of the present invention is to provide a bump structure including a metal core formed by wire bonding and encapsulated by a buffer encapsulant. A metal cap is formed on top of the buffer encapsulant to electrically connect to the metal core. Accordingly, a composite bump with excellent resistance of thermal stresses is formed to reduce or even eliminate metal fatigue in the bump without causing electrical shorts in the package.

According to the present invention, a bump structure comprises a metal core, a buffer encapsulant, and a metal cap, where the metal core is a stud bump formed by wire bonding and is encapsulated by the buffer encapsulant. The buffer encapsulant has a top surface where a metal cap is formed on the top surface to electrically connect to the metal core.

### DESCRIPTION OF THE DRAWINGS

FIG. 1 shows a cross sectional view of a bump structure disposed on a substrate according to the first embodiment of the present invention.

FIG. 2A to 2C shows cross sectional views of the bump structure during fabrication processes according to the first embodiment of the present invention.

FIG. 3 shows a cross sectional view of another bump structure disposed on a substrate according to the second embodiment of the present invention.

FIG. 4A to 4C shows cross sectional views of the bump structure during fabrication processes according to the second embodiment of the present invention.

### DETAIL DESCRIPTION OF THE INVENTION

Please refer to the attached drawings, the present invention will be described by means of embodiment(s) below.

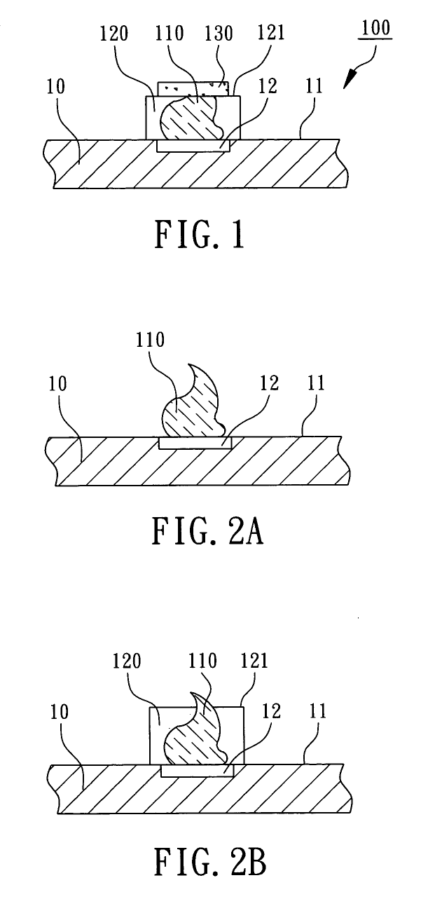

According to the first embodiment of the present invention, a bump structure is illustrated in FIG. 1. A bump structure 100 is disposed on a substrate 10 as an electrical terminal, which comprises a metal core 110, a buffer encapsulant 120 and a metal cap 130. The metal core 110 is a stud bump formed by wire bonding and is attached to the bonding pad 12 of the substrate 10. The material of the metal core 110 is selected from the group consisting of gold, aluminum, copper, and tin-lead, and normally is gold. The buffer encapsulant 120 has a top surface 121 and encapsulates the metal core 10. In the present embodiment, the buffer encapsulant 120 is in B-stage and can be formed by printing. The metal cap 130 is formed on the top surface 121 of the buffer encapsulant 120 and is electrically connected to the metal core 110. The material of the metal cap 130 is selected from the group of tin, tin-lead, copper, nickel, and gold. In this embodiment, the metal cap 130 is a copper pad plated with nickel and gold. Therefore, the bump structure 100 is a composite bump with excellent resistance of thermal stresses to reduce or even eliminate metal fatigue in the bump without causing electrical shorts in the package. Preferably, the area of the metal cap 130 is smaller than the top surface 121 of the buffer encapsulant 120 without covering the sidewalls of the buffer encapsulant 120 to avoid delamination from the buffer encapsulant 120.

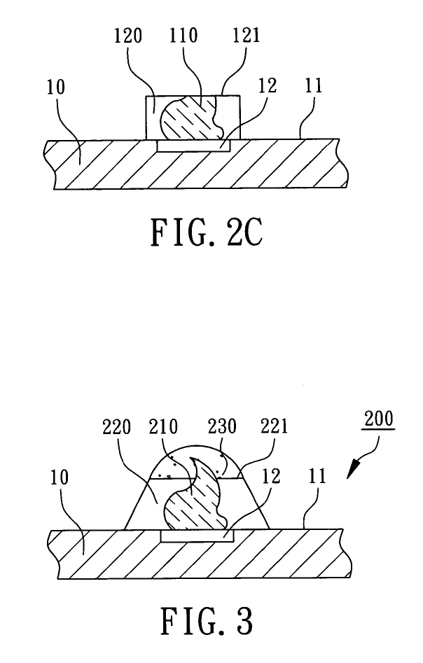

The fabrication processes of the bump structure 100 disposed on the substrate 10 are revealed from FIG. 2A to FIG. 2C. Firstly, as shown in FIG. 2A, a substrate 10 is provided where the substrate is selected from the group consisting of wafers, chips, semiconductor packages, printed circuit boards, and flexible printed circuit boards. The substrate 10 has a top surface 11 on which at least a bonding pad 12 is formed. Utilizing wire bonding technology, a stud bump is formed on the bonding pad 12 of the substrate 10 to be the metal core 110 of the bump structure 100. Then, as shown in FIG. 2B, a buffer encapsulant 120 is formed on the top surface 11 of the substrate 10 by stencil printing corresponding to the bonding pad 12 to encapsulate the metal core 110. The buffer encapsulant 120 has a top surface 121. In the present embodiment, the metal core 110 has a tip protruded from the top surface 121 of the buffer encapsulant 120. Preferably, as shown in FIG. 2C, the protruded portion of the metal core 110 is removed by a grounding step to planarize the top surface 121 of the buffer encapsulant 120 and to partially expose the metal core 110. Finally, as shown in FIG. 1, a metal cap 130 is disposed on the top surface 121 of the buffer encapsulant 120 by printing or plating or sputtering so that the metal cap 130 is electrically connected to the metal core 100. The bump structure 100 is fabricated.

Another bump structure 200 is revealed in FIG. 3 according to the second embodiment of the present invention. A bump structure 200 is disposed to the bonding pad 12 of the substrate 10 and comprises a metal core 210, a buffer encapsulant 220, and a metal cap 230 where the metal core 210 is a stud bump formed by wire bonding. The metal core 210 and the buffer encapsulant 220 are deformable and flexible such that the metal cap 230 is movable with respect with corresponding bonding pad 12 of the substrate 10. In this embodiment, the metal core 210 is a stud bump or a stack of multiply stud bumps. The buffer encapsulant 220 encapsulates the metal core 210 with the metal core 210 protruding from the top surface 221 of the buffer encapsulant 220. Normally, the buffer encapsulant 220 is in B-stage. The metal cap 230 is formed on the top surface 221 of the buffer encapsulant 220 to electrically connect to the metal core 210 where the metal cap 230 is formed by printing, plating, or sputtering. Preferably, the area of the metal cap 230 is smaller than the top surface 221 of the buffer encapsulant 220. The materials of the metal cap 230 is selected from the group of tin, lead, copper, nickel, or gold. Therefore, the bump structure 200 is a composite bump with excellent resistance of thermal stresses to reduce or even eliminate metal fatigue in the bump without causing electrical shorts in the package.

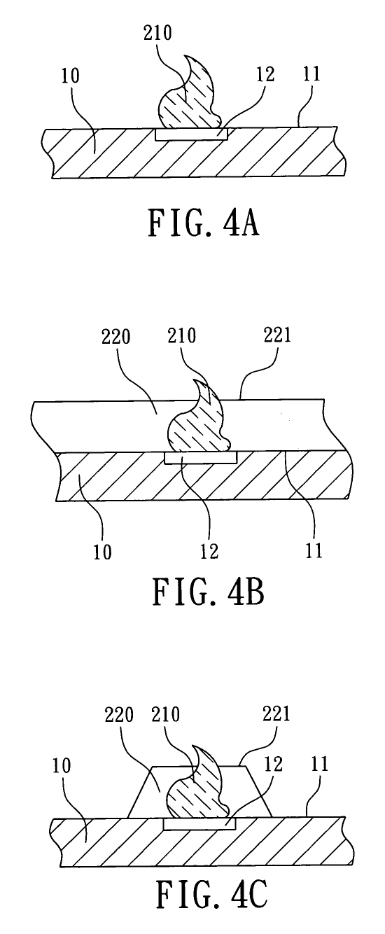

The fabrication processes of the bump structure 200 disposed on the substrate 10 are shown from FIG. 4A to 4C. Firstly, as shown in FIG. 4A, a substrate 10 is provided, which has a top surface 11 and at least a bonding pad 12. A metal core 210 of the bump structure 200 is a stud bump formed on the bonding pad 12 of the substrate 10 by wire bonding. Then, as shown in FIG. 4B, a buffer encapsulant 220 is formed on the top surface 11 of the substrate 10 to encapsulate the metal core 210 where the buffer encapsulant 220 is formed by spin coating, printing, or curtain coating to fully cover the top surface 11 of the substrate 10. The buffer encapsulant 220 has a top surface 221 where the metal core 210 is protruded from the top surface 221. Then, as shown in FIG. 4C, the buffer encapsulant 220 is patterned by photolithography to remove the unwanted portions of the buffer encapsulant 220 to form bump-like structures where the buffer encapsulant 220 is a photo-sensitive dielectric material such as polyimide (PI) or benzocyclobutene (BCB). Finally, a metal cap 230 is formed on the top surface 221 of the buffer encapsulant 220 by printing to encapsulate the exposed portion of the metal core 210 to electrically connect the metal cap 230

The above description of embodiments of this invention is intended to be illustrative and not limiting. Other embodiments of this invention will be obvious to those skilled in the art in view of the above disclosure.

What is claimed is:

1. A bump structure disposed on a substrate, comprising:
a metal core formed by wire-bonding wherein the metal core is a stud bump;
a buffer encapsulant encapsulating the metal core and having a top surface; and
a metal cap formed on the top surface of the buffer encapsulant and electrically connected to the metal core.

2. The bump structure of claim 1, wherein the materials of metal core is selected from the group consisting of gold, aluminum, copper, and tin-lead.

3. The bump structure of claim 1, wherein the materials of metal core is selected from the group consisting of tin, tin-lead, copper, nickel, and gold.

4. The bump structure of claim 1, wherein the buffer encapsulant is in B-stage.

5. The bump structure of claim 1, wherein the buffer encapsulant is made of polyimide (PI) or benzocyclobutene (BCB).

6. The bump structure of claim 1, wherein the metal core is attached to a bonding pad of the substrate, wherein the substrate is selected from the group consisting of wafer, chip, semiconductor package, printed circuit board, and flexible printed circuit board.

7. The bump structure of claim 1, wherein the buffer encapsulant is formed by printing, spin coating, or curtain coating.

8. The bump structure of claim 1 , wherein the metal cap is formed by printing, plating, or sputtering.

9. The bump structure of claim 1, wherein the area of the metal cap is smaller than the top surface of the buffer encapsulant.

10. A fabrication method of a bump structure, including:
providing a substrate having at least a bonding pad;
wire-bonding a stud bump on the bonding pad of the substrate to form a metal core;
forming a buffer encapsulant on the substrate to encapsulate the metal core, wherein the buffer encapsulant has a top surface; and
forming a metal cap on the top surface of the buffer encapsulant, the metal cap be electrically connected to the metal core.

11. The method of claim 10, wherein the buffer encapsulant is in B-stage.

12. The method of claim 10, wherein the substrate is selected from the group consisting of wafer, chip, semiconductor package, printed circuit board, and flexible printed circuit board.

13. The method of claim 10, wherein the buffer encapsulant is formed by printing, spin coating, or curtain coating.

14. The method of claim 13, further comprising a photolithographic process to pattern the buffer encapsulant.

15. The method of claim 14, wherein the buffer encapsulant is photo-sensitive dielectric materials of polyimide (PI) or benzocyclobutene (BCB).

16. The method of claim 10, wherein the metal cap is formed by printing, plating, or sputtering.

17. The method of claim 10, wherein the area of the metal cap is smaller than the top surface of the buffer encapsulant.

18. The method of claim 10, further comprising a grounding step to planarize the top surface of the buffer encapsulant and to expose the metal core.
